(19) United States
(12) Patent Application Publication
(10) Pub. No.: US 2026/0031279 A1
(43) Pub. Date: Jan. 29, 2026

(54) MULTILAYER CERAMIC ELECTRONIC DEVICE, CIRCUIT BOARD, AND PACKAGE

(71) Applicant: TAIYO YUDEN CO., LTD., Tokyo (JP)

(72) Inventors: Yoshiki IWAZAKI, Takasaki-shi (JP); Riki SUEMASA, Takasaki-shi (JP); Kenichi SHIMOMAI, Takasaki-shi (JP); Kazunari TAKEUCHI, Takasaki-shi (JP); Shinichi SASAKI, Takasaki-shi (JP); Yukihiro KONISHI, Takasaki-shi (JP)

(21) Appl. No.: 19/343,244

(22) Filed: Sep. 29, 2025

Related U.S. Application Data
(63) Continuation of application No. PCT/JP2023/041135, filed on Nov. 15, 2023.

(30) Foreign Application Priority Data
Mar. 30, 2023 (JP) 2023-056079

(51) Int. Cl. H01G 4/30; H01G 4/008; H05K 1/18

(52) U.S. Cl. CPC H01G 4/30; H01G 4/0085; H05K 1/181; H05K 2201/10015

(57) ABSTRACT

A multilayer ceramic electronic device includes an element body having a substantially rectangular parallelepiped shape in which a first internal electrode layer and a second internal electrode layer are alternately stacked with a dielectric layer sandwiched therebetween, and external electrodes formed on a surface of the element body so as to be spaced apart from each other, with the first internal electrode layer and the second internal electrode layer being drawn out thereto, respectively. The first internal electrode layer and the second internal electrode layer contain a sub-component in addition to a main component. The sub-component of the first internal electrode layer is different from the sub-component of the second internal electrode layer.

### CROSS-REFERENCE TO RELATED APPLICATION

This application is a continuation application of PCT/JP2023/041135 filed on Nov. 15, 2023, which claims priority to Japanese Patent Application No. 2023-056079 filed on Mar. 30, 2023, the contents of which are herein wholly incorporated by reference.

### FIELD

A certain aspect of the present disclosure relates to a multilayer ceramic electronic device, a circuit board, and a package.

### BACKGROUND

Multilayer ceramic electronic devices such as multilayer ceramic capacitors (MLCCs) have been developed for incorporation into a variety of electronic devices, including smartphones and personal computers (see, for example, International Publication No. 2022/210642, International Publication No. 2022/210629, International Publication No. 2022/210628, International Publication No. 2022/210627, International Publication No. 2022/210625, International Publication No. 2022/210624).

### SUMMARY OF THE INVENTION

According to an aspect of the present invention is a multilayer ceramic electronic device including: an element body having a substantially rectangular parallelepiped shape in which a first internal electrode layer and a second internal electrode layer are alternately stacked with a dielectric layer sandwiched therebetween; and external electrodes formed on a surface of the element body so as to be spaced apart from each other, with the first internal electrode layer and the second internal electrode layer being drawn out thereto, respectively, wherein the first internal electrode layer and the second internal electrode layer contain a sub-component in addition to a main component, and wherein the sub-component of the first internal electrode layer is different from the sub-component of the second internal electrode layer.

Another aspect of the present invention is a circuit board including: the above-mentioned multilayer ceramic electronic device; and a mounting board including a plurality of lands to which a first one of the external electrodes to which the first internal electrode layer is drawn out and a second one of the external electrodes to which the second internal electrode layer is drawn out are respectively connected.

Another aspect of the present invention is a package including: the above-mentioned multilayer ceramic electronic device; a carrier tape having a sealing face and a recess recessed from the sealing face for accommodating the multilayer ceramic electronic device; and a top tape attached to the sealing face and covering the recess.

### BRIEF DESCRIPTION OF THE DRAWINGS

FIG. 1 is a partial cross-sectional perspective view of a multilayer ceramic capacitor;

FIG. 2 is a cross-sectional view taken along line A-A in FIG. 1;

FIG. 3 is a cross-sectional view taken along line B-B in FIG. 1;

FIG. 4A is an enlarged cross-sectional view near a first external electrode;

FIG. 4B is an enlarged cross-sectional view near a second external electrode;

FIG. 5 is a diagram illustrating a continuity modulus;

FIG. 6 is a diagram illustrating a circuit board in which a multilayer ceramic capacitor is mounted on a mounting board;

FIG. 7 is a diagram illustrating a package;

FIG. 8 is a diagram illustrating a package;

FIG. 9 is a diagram illustrating a flow of a manufacturing method for a multilayer ceramic capacitor;

FIG. 10A and FIG. 10B are diagrams illustrating a stacking process;

FIG. 11 is a diagram illustrating a crimping process; and

FIG. 12 is a diagram illustrating attachment of a side margin portion.

### DETAILED DESCRIPTION

In order to make multilayer ceramic electronic devices smaller and with larger capacity, the dielectric layers are being made thinner. However, when making the dielectric layers thinner, the electric field strength applied to each dielectric layer becomes relatively higher. Therefore, there is a need to improve reliability when voltage is applied.

One way to improve reliability is to include a sub-component in the internal electrode. The sub-component of the internal electrode can increase the interface resistance between the dielectric and the electrode. However, if the components contained in the internal electrode layer used as the anode and the internal electrode layer used as the cathode are the same, there is a risk that high interface resistance is not obtained at the dielectric/internal electrode layer interface on both sides of the anode and cathode, and high reliability is not obtained.

Hereinafter, an exemplary embodiment will be described with reference to the accompanying drawings.

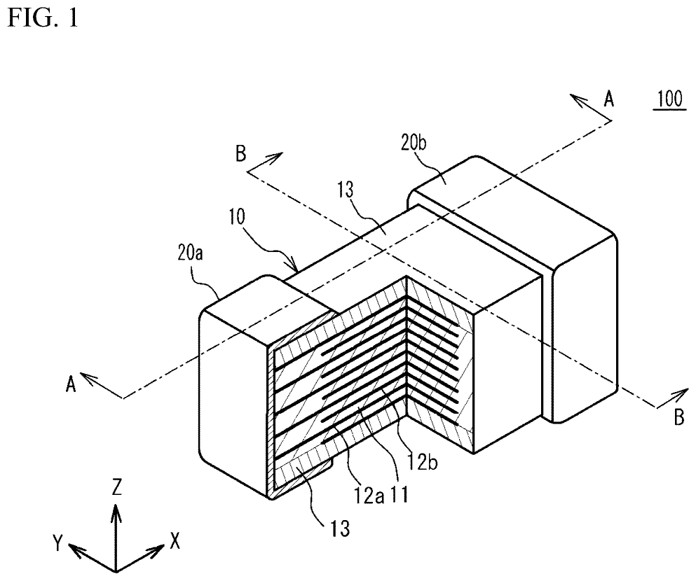

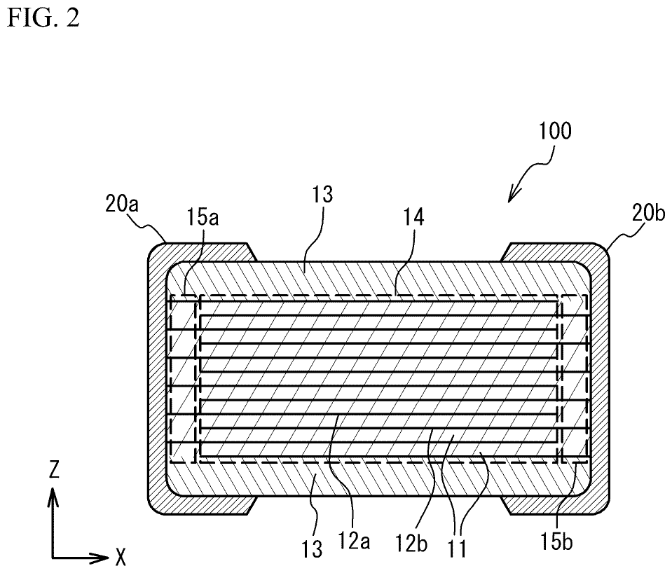

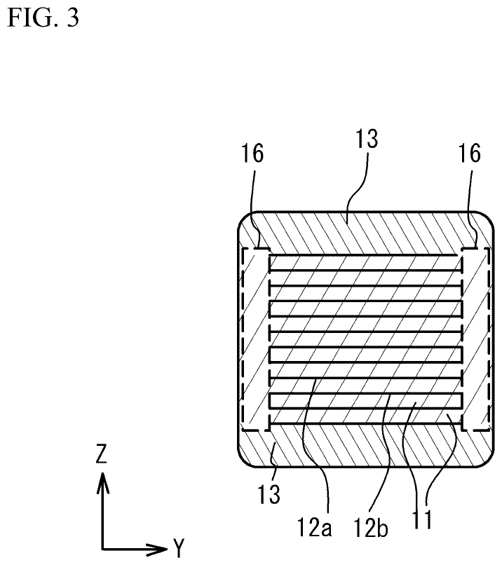

(Embodiment) FIG. 1 illustrates a perspective view of a multilayer ceramic capacitor 100, in which a cross section of a part of the multilayer ceramic capacitor 100 is illustrated. FIG. 2 is a cross-sectional view taken along line A-A in FIG. 1. FIG. 3 is a cross-sectional view taken along line B-B in FIG. 1. As illustrated in FIG. 1 to FIG. 3, the multilayer ceramic capacitor 100 includes an element body 10 having a rectangular parallelepiped shape. In the element body 10, the four surfaces other than the top and bottom surfaces in the stacking direction are referred to as side surfaces. In the element body 10, a first external electrode 20a and a second external electrode 20b are provided on two opposing side faces (a first side face and a second side face). The first external electrode 20a extends from the first side face to the four adjacent faces. The second external electrode 20b extends from the second side face to the four adjacent faces. However, the first external electrode 20a and the second external electrode 20b are spaced apart from each other.

In this embodiment, as an example, the first external electrode 20a is used as an anode, and the second external electrode 20b is used as a cathode. It is preferable to distinguish the first external electrode 20a from the second external electrode 20b by using a marker or other visual indication.

In FIG. 1 to FIG. 3, a Z-axis direction (first direction) is the stacking direction. The Z-axis direction is a direction in which internal electrode layers face each other. An X-axis direction (second direction) is a longitudinal direction of the element body 10. The X-axis direction is a direction in which the first side face and the second side face of the element body 10 are opposite to each other and in which the first external electrode 20a is opposite to the second external electrode 20b. A Y-axis direction (third direction) is a width direction of the internal electrode layers. The Y-axis direction is the direction in which two side faces (third and fourth side faces) other than the first and second side faces of the four side faces of the element body 10 face each other. The X-axis direction, the Y-axis direction and the Z-axis direction are vertical to each other.

The element body 10 has a configuration in which dielectric layers 11 containing a ceramic material that functions as a dielectric and internal electrode layers are alternately stacked. The internal electrode layers include a plurality of first internal electrode layers 12a and a plurality of second internal electrode layers 12b. The first internal electrode layers 12a and the second internal electrode layers 12b are alternately stacked. The edge of the first internal electrode layer 12a is drawn to the first side face of the element body 10 on which the first external electrode 20a is provided. The edge of the second internal electrode layer 12b is drawn to the second side face of the element body 10 on which the second external electrode 20b is provided. Thereby, the first internal electrode layers 12a and the second internal electrode layers 12b are alternately conductive to the first external electrode 20a and the second external electrode 20b. As a result, the multilayer ceramic capacitor 100 has a configuration in which capacitor units are stacked. In the multilayer body of the dielectric layers 11 and the internal electrode layers, two of the internal electrode layers are disposed as the outermost layers in the stacking direction, and the upper and lower faces of the multilayer body are covered with cover layers 13. The cover layers 13 are mainly composed of a ceramic material. For example, the cover layers 13 may have the same composition as the dielectric layers 11 or may have a different composition. In addition, as long as the first internal electrode layers 12a and the second internal electrode layers 12b are exposed in different regions on the surface of the multilayer body and are conductive to different external electrodes, the configuration is not limited to that illustrated in FIG. 1 to FIG. 3. The different regions on the surface of the multilayer body may be surface regions on opposing faces of the multilayer body, surface regions on adjacent faces of the multilayer body, or different surface regions on the same face of the multilayer body. As long as the different external electrodes are spaced apart from each other, the first internal electrode layers 12a and the second internal electrode layers 12b may extend from the faces exposed on the surface region of the multilayer body to other faces.

For example, the multilayer ceramic capacitor 100 may have a length of 0.25 mm, a width of 0.125 mm, and a height of 0.125 mm. The multilayer ceramic capacitor 100 may have a length of 0.4 mm, a width of 0.2 mm, and a height of 0.2 mm. The multilayer ceramic capacitor 100 may have a length of 0.6 mm, a width of 0.3 mm, and a height of 0.3 mm. The multilayer ceramic capacitor 100 may have a length of 1.0 mm, a width of 0.5 mm, and a height of 0.5 mm. The multilayer ceramic capacitor 100 may have a length of 3.2 mm, a width of 1.6 mm, and a height of 1.6 mm. The multilayer ceramic capacitor 100 may have a length of 4.5 mm, a width of 3.2 mm, and a height of 2.5 mm. However, the size of the multilayer ceramic capacitor 100 is not limited to the above sizes. The size of the multilayer ceramic capacitor 100 may be, for example, length>width≥height, width>length≥height, height>length≥width, or height>width≥length.

A main component of the dielectric layer 11 is a ceramic material having a perovskite structure expressed by a general formula ABO₃. The perovskite structure includes ABO_{3-α} having an off-stoichiometric composition. 0≤α≤1: a represents the amount that deviates from the stoichiometric composition: hereinafter, α will be omitted. For example, the ceramic material is such as BaTiO₃ (barium titanate), CaZrO₃ (calcium zirconate), CaTiO₃ (calcium titanate), SrTiO₃ (strontium titanate), MgTiO₃ (magnesium titanate), Ba_{1-x-y}CaₓSr_{y}Ti_{1-z}Zr₂O₃ (0≤x≤1, 0≤y≤1, 0≤z≤1) having a perovskite structure. Ba_{1-x-y}CaₓSr_{y}Ti_{1-z}Zr₂O₃ may be barium strontium titanate, barium calcium titanate, barium zirconate, barium titanate zirconate, calcium titanate zirconate, barium calcium titanate zirconate or the like. For example, the dielectric layer 11 contains 50 at % or more of the main component ceramic, for example 90 at % or more. The thickness of the dielectric layer 11 is, for example, 5.0 μm or less, 3.0 μm or less, 1.0 μm or less, 0.5 μm or less, 0.4 μm or less, 0.3 μm or less, or 0.2 μm or less. The thickness of the dielectric layer 11 can be measured by observing a cross section of the multilayer ceramic capacitor 100 with a SEM (scanning electron microscope), measuring the thickness at 10 points for each of 10 different dielectric layers 11, and deriving the average value of all the measurement points.

Additives may be added to the dielectric layer 11. As additives to the dielectric layer 11, zirconium (Zr), magnesium (Mg), manganese (Mn), molybdenum (Mo), vanadium (V), chromium (Cr), rare earth elements (Scandium (Sc), Cerium (Ce), Neodymium (Nd), yttrium (Y), samarium (Sm), europium (Eu), gadolinium (Gd), terbium (Tb), dysprosium (Dy), holmium (Ho), erbium (Er), thulium (Tm), and ytterbium (Yb)) or an oxide of cobalt (Co), nickel (Ni), lithium (Li), boron (B), sodium (Na), potassium (K) or silicon (Si), or a glass including cobalt, nickel, lithium, boron, sodium, potassium or silicon.

As illustrated in FIG. 2, the section where the first internal electrode layers 12a connected to the first external electrode 20a faces the second internal electrode layers 12b connected to the second external electrode 20b is a section where capacity is generated in the multilayer ceramic capacitor 100. Thus, this section is referred to as a capacity section 14. That is, the capacity section 14 is a section where two adjacent internal electrode layers connected to different external electrodes face each other.

The section where the first internal electrode layers 12a connected to the first external electrode 20a face each other without the second internal electrode layers 12b connected to the second external electrode 20b interposed therebetween is referred to as a first end margin 15a. The section where the second internal electrode layers 12b connected to the second external electrode 20b face each other without the first internal electrode layers 12a connected to the first external electrode 20a interposed therebetween is a second end margin 15b. That is, the end margin is a section where the internal electrode layers connected to one of the external electrodes face each other with no internal electrode layer connected to the other of the external electrodes interposed therebetween. The first end margin 15a and the second end margin 15b are sections where no capacity is generated.

As illustrated in FIG. 3, in the element body 10, a side margin 16 is a section provided so as to cover the ends (ends in the Y-axis direction) of the third side face and the fourth side face of the dielectric layers 11, the first internal electrode layers 12a and the second internal electrode layers 12b. That is, the side margin 16 is a section provided outside the capacity section 14 in the Y-axis direction. The side margin 16 is also a section where no capacity is generated.

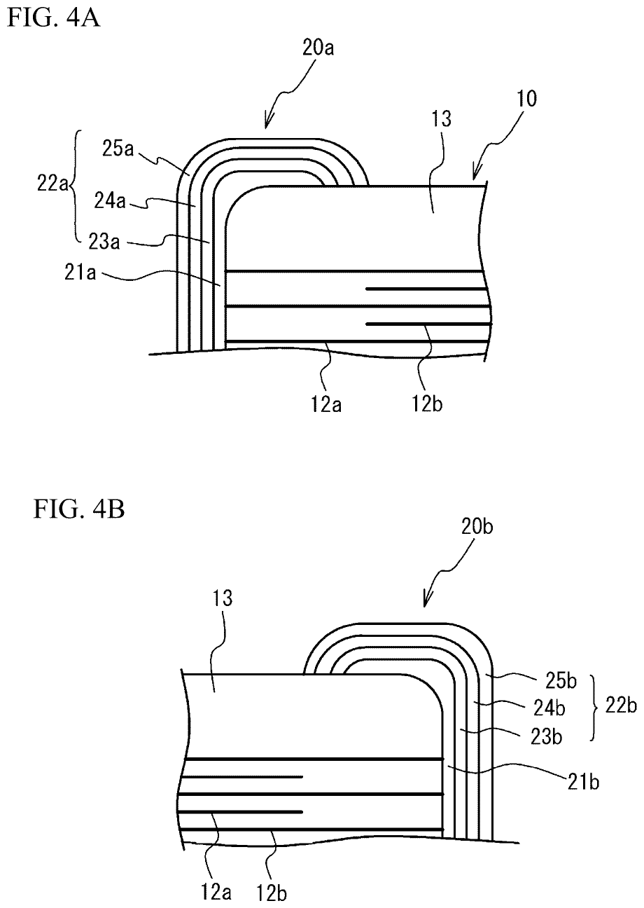

FIG. 4A is an enlarged cross-sectional view of the vicinity of the first external electrode 20a. Hatching is omitted in FIG. 4A. As illustrated in FIG. 4A, the first external electrode 20a has a structure in which a plated layer 22a is provided on a base layer 21a. The base layer 21a is mainly composed of nickel, copper, or the like. The base layer 21a may contain ceramic grains as a co-material, or may contain a glass component. The plated layer 22a is mainly composed of a metal such as nickel, copper, aluminum, zinc, tin or the like, or an alloy of two or more of these. The plated layer 22a may be a plated layer of a single metal component, or may be a plurality of plated layers of mutually different metal components. For example, in FIG. 4A, the plated layer 22a has a structure in which a first plated layer 23a, a second plated layer 24a, and a third plated layer 25a are formed in this order from the base layer 21a side. The first plated layer 23a is, for example, a copper-plated layer. The second plated layer 24a is, for example, a nickel-plated layer. The third plated layer 25a is, for example, a tin-plated layer.

FIG. 4B is an enlarged cross-sectional view of the vicinity of the second external electrode 20b. Hatching is omitted in FIG. 4B. As illustrated in FIG. 4A, the second external electrode 20b has a structure in which a plated layer 22b is provided on a base layer 21b. The base layer 21b is mainly composed of nickel, copper, or the like. The base layer 21b may contain ceramic grains as a co-material, or may contain a glass component. The plated layer 22b is mainly composed of a metal such as nickel, copper, aluminum, zinc, tin or the like, or an alloy of two or more of these. The plated layer 22b may be a plated layer of a single metal component, or may be a plurality of plated layers of mutually different metal components. For example, in FIG. 4B, the plated layer 22b has a structure in which a first plated layer 23b, a second plated layer 24b, and a third plated layer 25b are formed in this order from the base layer 21b side. The first plated layer 23b is, for example, a copper-plated layer. The second plated layer 24b is, for example, a nickel-plated layer. The third plated layer 25b is, for example, a tin-plated layer.

The base layer 21a and the base layer 21b may have the same composition, or may have different compositions. The plated layer 22a and the plated layer 22b may have the same layered structure, or may have different layered structures. For example, the number of layers of the plated layers may be different. The first plated layer 23a and the first plated layer 23b may have the same composition, or may have different compositions. The second plated layer 24a and the second plated layer 24b may have the same composition, or may have different compositions. The third plated layer 25a and the third plated layer 25b may have the same composition, or may have different compositions.

In order to achieve a smaller size and a larger capacity in the multilayer ceramic capacitor 100, it is necessary to make the dielectric layer thinner. However, when the dielectric layer is made thinner, the electric field strength applied to each dielectric layer becomes relatively high. Therefore, it is necessary to improve the reliability when a voltage is applied. However, if the components contained in the internal electrode layer used as the anode and the components contained in the internal electrode layer used as the cathode are the same, there is a risk that high interfacial resistance is not obtained at the dielectric/internal electrode layer interfaces on both sides of the anode and cathode, and high reliability is not obtained.

The multilayer ceramic capacitor 100 according to this embodiment has a structure that can provide high reliability. Details are described below.

The first internal electrode layer 12a and the second internal electrode layer 12b each contain a sub-component in addition to a main component. The main component is contained in each internal electrode layer at 50 at % or more. The sub-component contained in the first internal electrode layer 12a is different from the sub-component contained in the second internal electrode layer 12b. This structure provides high interface resistance at both the interface between the first internal electrode layer 12a and the dielectric layer 11 and the interface between the second internal electrode layer 12b and the dielectric layer 11. This makes it possible to provide high reliability when using each of the first internal electrode layer 12a and the second internal electrode layer 12b as either an anode or a cathode.

The first internal electrode layer 12a and the second internal electrode layer 12b are mainly composed of base metals such as nickel (Ni), copper (Cu), and tin (Sn), or alloys containing these. The main components of the first internal electrode layer 12a and the second internal electrode layer 12b may be noble metals such as platinum (Pt), palladium (Pd), silver (Ag), or gold (Au), or alloys containing these. The main components of the first internal electrode layer 12a and the second internal electrode layer 12b may be the same or different. As an example, the main components of the first internal electrode layer 12a and the second internal electrode layer 12b may both be the same, that is, nickel, or may both be the same, that is, copper.

The subcomponents in the first internal electrode layer 12a and the second internal electrode layer 12b are, for example, one or more of the following elements that do not overlap with the main components: iron (Fe), chromium (Cr), tin (Sn), vanadium (V), hafnium (Hf), osmium (Os), ruthenium (Ru), silicon (Si), boron (B), rhenium (Re), copper (Cu), cobalt (Co), tungsten (W), germanium (Ge), manganese (Mn), tantalum (Ta), silver (Ag), niobium (Nb), molybdenum (Mo), gallium (Ga), aluminum (Al), zinc (Zn), indium (In), zirconium (Zr), magnesium (Mg), titanium (Ti), thallium (Ti), scandium (Sc), yttrium (Y), or lanthanoid elements.

Here, the effect of the sub-components contained in the first internal electrode layer 12a being different from the sub-components contained in the second internal electrode layer 12b will be described in detail.

As the deterioration of the multilayer ceramic capacitor 100 progresses, donor defects (mainly oxygen vacancies) accumulate in the second internal electrode layer 12b connected to the second external electrode 20b used as the cathode, and electron conduction becomes dominant, while hole conduction associated with acceptor defects becomes dominant in the first internal electrode layer 12a connected to the first external electrode 20a used as the anode. In other words, since the mechanisms of electrical conduction are different on both electrodes, there is a risk that high reliability is not obtained even if the same additive element is added as a sub-component to both electrodes.

When an element with a high work function is added as a sub-component to the second internal electrode layer 12b, the interface resistance to electrons increases, and the above-mentioned desirable results are obtained. On the other hand, when an element with a high work function is added as a sub-component to the first internal electrode layer 12a, the interface resistance to holes decreases, and the opposite state to the desirable work function may occur, and there is a risk that high reliability is not obtained. The work function here refers to the minimum energy required to extract one electron from the surface of a material to an infinite distance.

Similarly, when an element with a low work function is added as a sub-component to the first internal electrode layer 12a, the interface resistance to holes increases, and the above-mentioned desirable results are obtained. On the other hand, when an element with a low work function is added as a sub-component to the second internal electrode layer 12b, the interface resistance to electrons decreases, which is the opposite of the desirable work function, and there is a risk that high reliability is not obtained.

In contrast, in this embodiment, the sub-component contained in the first internal electrode layer 12a is different from the sub-component contained in the second internal electrode layer 12b.

To realize such an embodiment, it is preferable that the main component metal element of the first internal electrode layer 12a constituting the anode side and the main component metal element of the second internal electrode layer 12b constituting the cathode satisfy the following conditions.

1) The main metal element constituting the first internal electrode layer 12a and the main metal element constituting the second internal electrode layer 12b are the same, or are different but have the same work functions.

In this case, as described above, high reliability can be obtained by adding an element with a high work function as a sub-component to the second internal electrode layer 12b to increase the interface resistance to electrons, and adding an element with a low work function as a sub-component to the first internal electrode layer 12a to increase the interface resistance to holes.

2) The main metal element constituting the first internal electrode layer 12a and the main metal element constituting the second internal electrode layer 12b are different metal elements but have similar values that can be considered to be approximately equal in work functions.

In this case, “close enough to be considered to be approximately equal” means, for example, that the difference is within 0.05 eV, and more preferably within 0.02 eV. In this way, when the difference in work function of the main component metal elements is small, the change due to the work function of the metal element added as the sub-component is larger, and it can be treated the same as when the main component metal element constituting the first internal electrode layer 12a and the main component metal element constituting the second internal electrode layer 12b are the same.

3) When the main component metal element constituting the first internal electrode layer 12a and the main component metal element constituting the second internal electrode layer 12b are different metal elements, but the work function of the main component constituting the second internal electrode layer 12b is higher than the work function of the main component constituting the first internal electrode layer 12a.

Even with only main component metal elements, the work function of the second internal electrode layer 12b is high and by adding an element with a high work function as the sub-component, the interface resistance to electrons can be further increased, and the work function of the first internal electrode layer 12a is low and by adding an element with a low work function as the sub-component, the interface resistance to holes can be further increased. This is a preferable embodiment in which higher reliability can be obtained compared to the case where the main component metal elements are equal between the first internal electrode layer 12a and the second internal electrode layer 12b.

When the main component metal element constituting the first internal electrode layer 12a is different from the main component metal element constituting the second internal electrode layer 12b, and the work function of the main component metal element constituting the first internal electrode layer 12a is greater than the work function of the main component metal element constituting the second internal electrode layer 12b by more than 0.05 eV, and the difference between the two work functions is so large that it cannot be considered to be approximately equal, even if an element with a slightly higher work function is added as the sub-component, there is a risk that the low work function of the main component in the second internal electrode layer 12b is not compensated for, and the interface resistance to electrons is not increased, so that the desirable result of increasing reliability is not obtained. Similarly, even if an element with a slightly lower work function is added as the sub-component to the first internal electrode layer 12a, there is a risk that the high work function of the main component in the first internal electrode layer 12a is not compensated for, and the interface resistance to holes are not increased, so that the desirable result of increasing reliability is not obtained.

For this reason, it is preferable that (work function of the main metallic element constituting the first internal electrode layer 12a)−(work function of the main metallic element constituting the second internal electrode layer 12b)≤0.05 eV.

For example, it is preferable that the first internal electrode layer 12a contains nickel as the main component and at least one element selected from iron, chromium, tin, vanadium, hafnium, osmium, ruthenium, silicon, boron, rhenium, copper, cobalt, tungsten, germanium, manganese, tantalum, silver, niobium, molybdenum, gallium, aluminum, zinc, indium, zirconium, magnesium, titanium, thallium, scandium, yttrium, or lanthanoid elements as the sub-component, and that the second internal electrode layer 12b contains nickel as the main component and at least one element selected from gold, platinum, iridium, palladium, or selenium as the sub-component. For example, it is preferable that the first internal electrode layer 12a contains copper as the main component and at least one element selected from iron, chromium, tin, vanadium, hafnium, tungsten, germanium, manganese, tantalum, silver, niobium, molybdenum, gallium, aluminum, zinc, indium, zirconium, magnesium, titanium, thallium, scandium, yttrium, or lanthanoid elements as the sub-component, and the second internal electrode layer 12b contains copper as the main component and at least one element selected from gold, platinum, iridium, palladium, selenium, osmium, ruthenium, rhodium, silicon, or boron as the sub-component. For example, the main components of the first internal electrode layer 12a and the second internal electrode layer 12b may be the same metal element or a combination of different metal elements. In this case, the sub-component element is selected for each main component of each internal electrode layer. The condition is that the second internal conductor electrode layer has a higher work function than the first internal electrode layer in terms of the sub-component element relative to the main component element. For example, the main component of the first internal electrode layer 12a may be nickel and the main component of the second internal electrode layer 12b may be copper, or the main component of the first internal electrode layer 12a may be copper and the main component of the second internal electrode layer 12b may be nickel.

In the first internal electrode layer 12a, the amount of the sub-component is, for example, 0.01 at % or more and 10.0 at % or less, or 0.05 at % or more and 5.0 at % or less, or 0.1 at % or more and 3.0 at % or less. In the second internal electrode layer 12b, the amount of the sub-component is, for example, 0.01 at % or more and 10.0 at % or less, or 0.05 at % or more and 5.0 at % or less, or 0.1 at % or more and 3.0 at % or less.

The sub-component may be segregated in each internal electrode layer. For example, the sub-component may be segregated on the surface of each internal electrode layer. If the sub-component segregates, the fluctuation in work function increases, and the interfacial resistance at the interface between the dielectric layer and the internal electrode layer increases. The segregation state differs depending on the element of the sub-component. The segregation state may be uniform as a layer at the interface, or it may be locally segregated. Since the segregated portion acts as a barrier, an effect can be obtained if the sub-component segregates even locally at the interface, but a state in which the sub-component forms a layer at the interface will be more effective.

The average thickness per layer of the first internal electrode layer 12a and the second internal electrode layer 12b in the Z-axis direction is, for example, 1.5 μm or less, 1.0 μm or less, 0.7 μm or less, 0.5 μm or less, 0.3 μm or less, or 0.1 μm or less. The thickness of the first internal electrode layer 12a and the second internal electrode layer 12b can be measured by observing the cross section of the multilayer ceramic capacitor 100 with a SEM (scanning electron microscope), measuring the thickness at 10 points for each of the 10 different internal electrode layers, and deriving the average value of all the measurement points.

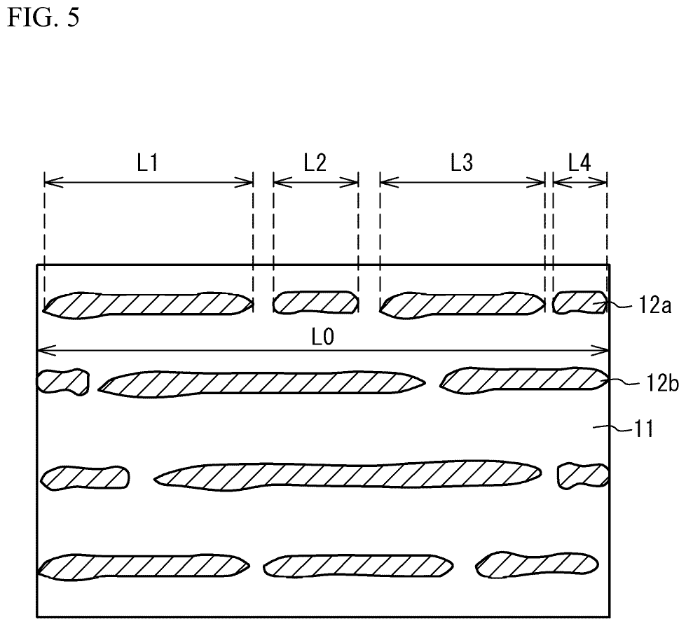

The continuity modulus of the first internal electrode layer 12a and the continuity modulus of the second internal electrode layer 12b may be different, but since an internal electrode layer with significantly poor continuity modulus deteriorates reliability, it is preferable that the continuity modulus of both internal electrode layers is 50% or more, preferably 60% or more, and more preferably 80% or more. As illustrated in FIG. 5, in an observation area of length L0 in a certain internal electrode layer, the lengths L1, L2, . . . , Ln of the metal parts are measured and summed up, and the ratio of the metal parts, Σ Ln/L0, can be defined as the continuity modulus of that layer.

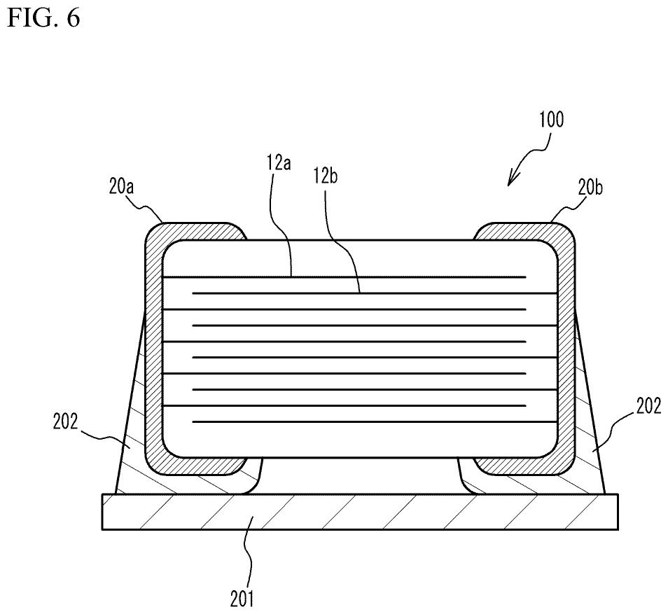

FIG. 6 is a diagram illustrating a circuit board in which the multilayer ceramic capacitor 100 is mounted on a mounting board 201. As illustrated in FIG. 6, the lower face in the stacking direction is arranged to face the land on the mounting board 201. The first external electrode 20a and the second external electrode 20b are each independently electrically connected to the mounting board 201 via a solder 202 with respect to the land on the mounting board 201. Since the first external electrode 20a is used as an anode, the second external electrode 20b is grounded.

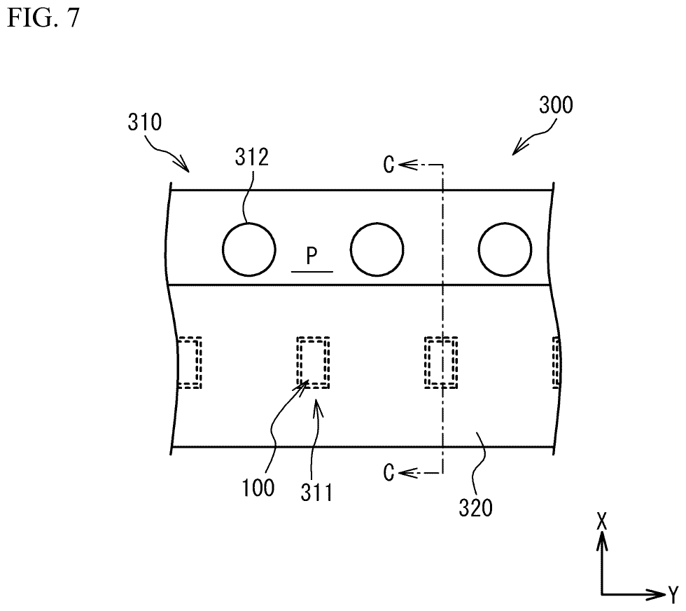

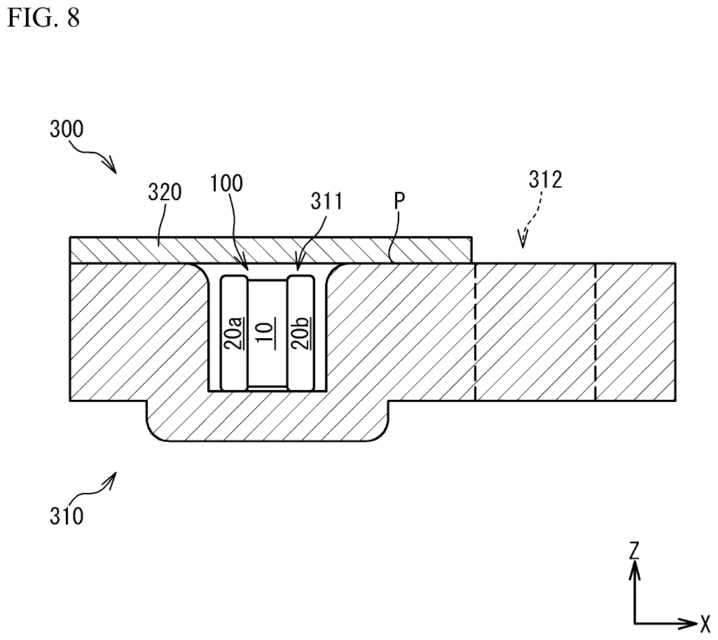

The multilayer ceramic capacitor 100 is prepared in a packaged state as a package 300 when mounted on the mounting board 201. FIG. 7 and FIG. 8 are diagrams illustrating the package 300. FIG. 7 is a partial plan view of the package 300. FIG. 8 is a cross-sectional view of the package 300 taken along a line CC in FIG. 7.

The package 300 comprises the multilayer ceramic capacitor 100, a carrier tape 310, and a top tape 320. The carrier tape 310 is configured as a long tape extending in the Y-axis direction. The carrier tape 310 has a plurality of recesses 311 arranged at intervals in the Y-axis direction, each of which accommodates each of the multilayer ceramic capacitors 100.

The carrier tape 310 has a seal face P, which is an upward face orthogonal to the Z-axis direction, and the plurality of recesses 311 are recessed downward in the Z-axis direction from the seal face P. In other words, the carrier tape 310 is configured so that the multilayer ceramic capacitors 100 in the plurality of recesses 311 can be removed from the seal face P side.

The carrier tape 310 has multiple feed holes 312 that penetrate in the Z-axis direction and are arranged at intervals in the Y-axis direction at positions offset in the X-axis direction from the row of the plurality of recesses 311. The feed holes 312 are configured as engagement holes used by the tape transport mechanism to transport the carrier tape 310 in the Y-axis direction.

In the package 300, the top tape 320 is attached to the seal face P of the carrier tape 310 along the row of the plurality of recesses 311, and the plurality of recesses 311 containing the multilayer ceramic capacitors 100 are collectively covered by the top tape 320. As a result, each of the plurality of multilayer ceramic capacitors 100 is held in each of the plurality of recesses 311.

As illustrated in FIG. 8, in the multilayer ceramic capacitor 100 in the recess 311 of the carrier tape 310, the main face of the element body 10 facing upward in the Z-axis direction faces the top tape 320. In addition, the main face of the element body 10 facing downward in the Z-axis direction faces the bottom face of the recess 311. Within the recess 311, it is determined that one side in the X-axis direction is the first external electrode 20a, and the other is the second external electrode 20b.

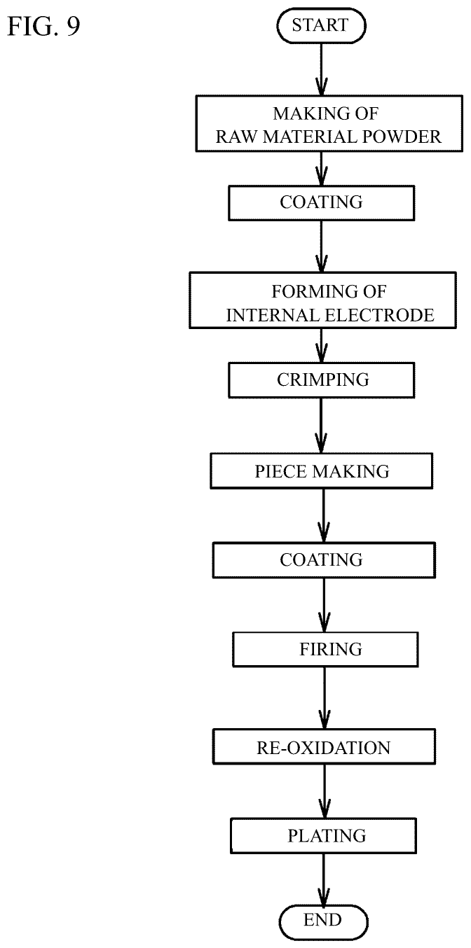

Next, a description will be given of a manufacturing method of the multilayer ceramic capacitors 100. FIG. 9 illustrates a manufacturing method of the multilayer ceramic capacitor 100.

(Making process of raw material powder) A dielectric material for forming the dielectric layer 11 is prepared. An A site element and a B site element are included in the dielectric layer 11 in a sintered phase of grains of ABO₃. For example, barium titanate is tetragonal compound having a perovskite structure and has a high dielectric constant. Generally, barium titanate is obtained by reacting a titanium material such as titanium dioxide with a barium material such as barium carbonate and synthesizing barium titanate.

A predetermined additive compound is added to the obtained dielectric powder according to the purpose. As additives to the dielectric layer 11, zirconium (Zr), magnesium (Mg), manganese (Mn), molybdenum (Mo), vanadium (V), chromium (Cr), rare earth elements (Scandium (Sc), Cerium (Ce), Neodymium (Nd), Yttrium (Y), Samarium (Sm), Europium (Eu), Gadolinium (Gd), Terbium (Tb), Dysprosium (Dy), Holmium (Ho), Erbium (Er), Thulium (Tm), and Ytterbium (Yb)) or an oxide of cobalt (Co), nickel (Ni), lithium (Li), boron (B), sodium (Na), potassium (K) or silicon (Si), or a glass including cobalt, nickel, lithium, boron, sodium, potassium or silicon.

For example, a ceramic material is prepared by wet-mixing a compound containing an additive compound with a ceramic raw material powder, drying and pulverizing the mixture. For example, the ceramic material obtained as described above may be pulverized to adjust the particle size, if necessary, or may be combined with a classification process to adjust the particle size. Through the above steps, a dielectric material is obtained.

(Coating process) Next, a binder such as polyvinyl butyral (PVB) resin, an organic solvent such as ethanol or toluene, and a plasticizer are added to the obtained dielectric material and wet-mixed. Using the obtained slurry, a ceramic green sheet 51 is formed on a base material by, for example, a die coater method or a doctor blade method, and dried. The substrate is, for example, polyethylene terephthalate (PET) film. The process is not illustrated.

(Internal electrode formation process) As described above, the first internal electrode layer 12a and the second internal electrode layer 12b are mainly composed of base metals such as nickel (Ni), copper (Cu), and tin (Sn), or alloys containing these. Noble metals such as platinum (Pt), palladium (Pd), silver (Ag), and gold (Au), or alloys containing these, may also be used. The main component in the first internal electrode layer 12a and the main component in the second internal electrode layer 12b may be the same or different. As an example, the main component of the first internal electrode layer 12a and the second internal electrode layer 12b may both be the same, that is, nickel.

The sub-components in the first internal electrode layer 12a and the second internal electrode layer 12b are one or more of the following that do not overlap with the main components: gold (Au), tin (Sn), chromium (Cr), iron (Fe), yttrium (Y), indium (In), arsenic (As), cobalt (Co), nickel (Ni), copper (Cu), iridium (Ir), magnesium (Mg), osmium (Os), palladium (Pd), platinum (Pt), rhenium (Re), rhodium (Rh), ruthenium (Ru), selenium (Se), tellurium (Te), zinc (Zn), germanium (Ge), vanadium (V), aluminum (Al), silicon (Si), or the like.

The first metal conductor paste for forming the precursor of the first internal electrode layer 12a is prepared by kneading the main component selected from the above, the sub-component selected from the above, which has a lower work function than the selected main component, an organic binder, and a solvent. The second metal conductor paste for forming the precursor of the second internal electrode layer 12b is prepared by kneading the main component selected from the above, and the sub-component selected from the above, which has a higher work function than the selected main component, an organic binder, and a solvent.

The main component metal of the first metal conductor paste and the main component metal of the second metal conductor paste are selected so that one of the following three conditions is satisfied: the metal element of the main component of the second metal conductor paste is the same type as the metal element of the main component of the first metal conductor paste, the difference in work function is within 0.05 eV, or the work function of the metal element of the main component of the second metal conductor paste is greater than the work function of the metal element of the main component of the first metal conductor paste.

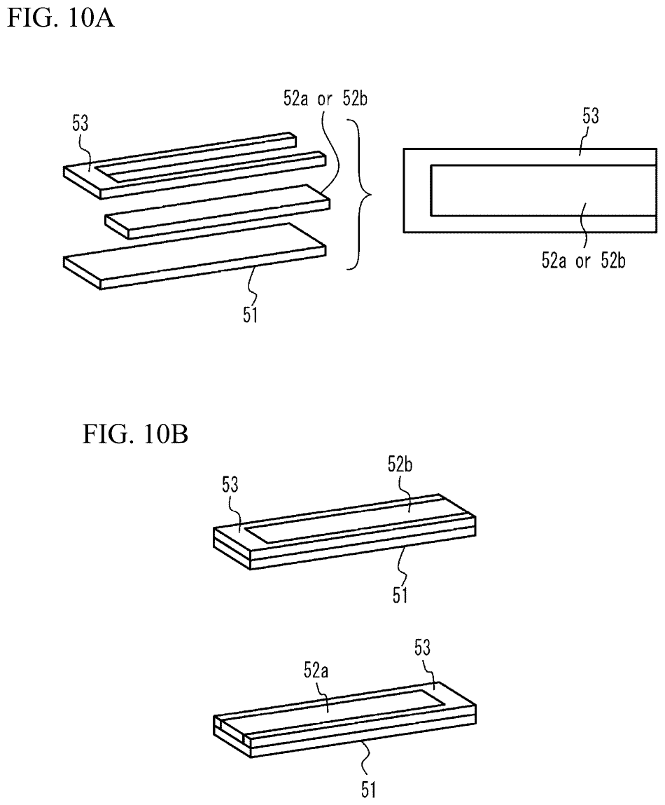

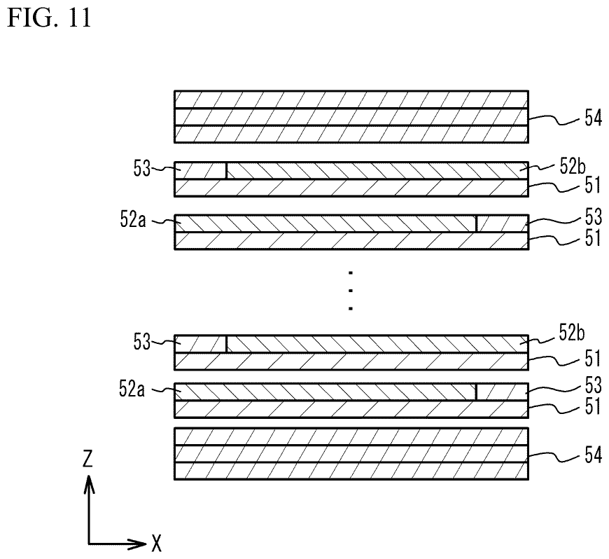

Next, as illustrated in FIG. 10A, a metal conductive paste for forming an internal electrode containing an organic binder is printed on the surface of the ceramic green sheet 51 by screen printing, gravure printing, or the like to arrange a first internal electrode pattern 52a for the first internal electrode layer 12a or a second internal electrode pattern 52b for the second internal electrode layer 12b. A first metal conductor paste is used to make the first internal electrode layer 12a, and a second metal conductor paste is used to make the second internal electrode layer 12b. Ceramic particles can also be added to the metal conductive paste as a co-material. The main component of the ceramic particles is not particularly limited, but is preferably the same as the main component ceramic of the dielectric layer 11. When ceramic particles are added as a co-material, they can be added when the first metal conductor paste and the second metal conductor paste are mixed. The method for forming the internal electrodes is not limited to printing, and plating, vacuum deposition, sputtering, and CVD may also be used.

Next, a binder such as ethyl cellulose and an organic solvent such as terpineol are added to the dielectric pattern material obtained in the making process of the raw material powder, and the mixture is kneaded in a roll mill to form a dielectric pattern paste for the reverse pattern layer. As illustrated in FIG. 10A, a dielectric pattern 53 is formed by printing the resulting slurry in the peripheral region, where the internal electrode pattern is not printed, on the ceramic green sheet 51 to cause the dielectric pattern 53 and the internal electrode pattern to form a flat surface. The ceramic green sheet 51 on which the internal electrode pattern and the dielectric pattern 53 are printed is referred to as a stack unit.

Thereafter, as illustrated in FIG. 10B, a predetermined number of stack units are stacked so that the internal electrode layers and the dielectric layers are alternated with each other and the end edges of the internal electrode layers are alternately exposed to both end faces in the length direction of the dielectric layer so as to be alternately led out to a pair of the external electrodes of different polarizations. Specifically, the ceramic green sheet 51 on which the first internal electrode pattern 52a and the dielectric pattern 53 are printed and the ceramic green sheet 51 on which the second internal electrode pattern 52b and the dielectric pattern 53 are printed are stacked in this order. For example, the number of the stack units is 100 to 500.

(Crimping process) A predetermined number (for example, 2 to 10) cover sheets are stacked on the stacked stack units and under the stacked stack units. After that, the stacked structure is thermally crimped.

(Pieces making process) The crimped compact is diced into individual pieces. Any existing method can be used for the pieces making process, such as dicing with a dicer or laser cutting.

(Coating process) The ceramic multilayer body obtained in this way is de-bindered in an N₂ atmosphere, and then coated with a metal paste that will become the base layers 21a and 21b by dipping.

(Firing process) After that, a firing is performed for 5 minutes to 10 hours in a reducing atmosphere with an oxygen partial pressure of 10-5 to 10-8 atm in a temperature of 1100° C. to 1300° C.

(Re-oxidation process) In order to return oxygen to the partially reduced main phase barium titanate of the dielectric layer 11 fired in a reducing atmosphere, N₂ and water vapor are mixed at about 1000° C. to an extent that the first internal electrode layer 12a and the second internal electrode layer 12b are not oxidized, heat treatment may be performed in gas or in the atmosphere at 500° C. to 700° C. This process is called a re-oxidation process.

(Plating process) After that, a metal coating of copper, nickel, tin or the like is applied to the base layer 21a by plating. Also, a metal coating of copper, nickel, tin or the like is applied to the base layer 21b by plating. Through these processes, the multilayer ceramic capacitor 100 is completed.

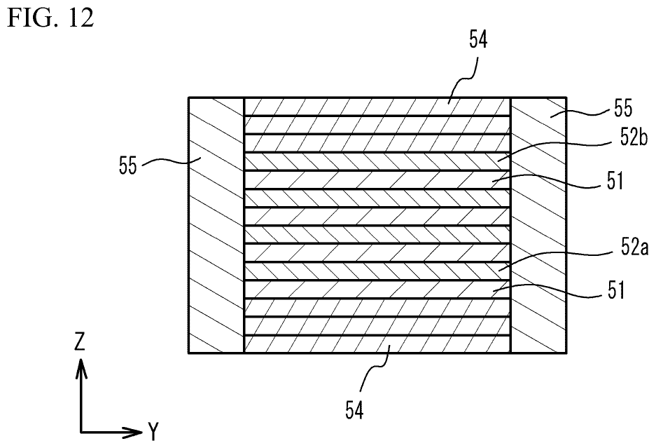

The above process is an example, and for example, reverse pattern printing may not be performed. Also, the side margin portions may be formed separately without reverse pattern printing. In this case, a dielectric pattern material for forming the side margins 16 is prepared in advance. The dielectric pattern material contains powder of the main component ceramic of the side margins 16. For example, powder of the main component ceramic of the dielectric material may be used as the powder of the main component ceramic. A specific additive compound may also be added depending on the purpose. The side margin portions may be attached or applied to the side of the individualized multilayer portion. Specifically, as illustrated in FIG. 12, the ceramic green sheet 51, and the first internal electrode pattern 52a and the second internal electrode pattern 52b having the same width as the ceramic green sheet 51 are stacked and then individualized to obtain multilayer portions. Next, a sheet formed of a dielectric pattern paste may be attached to the side of the multilayer portion as a side margin portion 55.

In the above, the base layer for the external electrodes and the ceramic multilayer body are fired at the same time, but this is not limited to this. For example, after firing the ceramic multilayer body, a Ni, Cu, Ag paste may be applied and baked, or the external electrodes may be formed by plating or sputtering techniques.

In addition, while the above embodiment is applied to a multilayer ceramic capacitor with two terminal electrodes, it may also be applied to a multilayer ceramic capacitor with three or more terminals. In particular, since three-terminal capacitors that are generally used at high frequencies with low ESL are required to have a sufficiently low ESR, the dielectric layer described in the above embodiment is also suitable for three-terminal capacitors.

Note that in each of the above embodiments, a multilayer ceramic capacitor has been described as an example of a multilayer ceramic electronic device, but the present invention is not limited thereto. For example, other multilayer ceramic electronic devices such as varistors and thermistors may be used.

Although the embodiments of the present invention have been described in detail, it is to be understood that the various change, substitutions, and alterations could be made hereto without departing from the spirit and scope of the invention.

What is claimed is:

1. A multilayer ceramic electronic device comprising:
an element body having a substantially rectangular parallelepiped shape in which a first internal electrode layer and a second internal electrode layer are alternately stacked with a dielectric layer sandwiched therebetween; and
external electrodes formed on a surface of the element body so as to be spaced apart from each other, with the first internal electrode layer and the second internal electrode layer being drawn out thereto, respectively,
wherein the first internal electrode layer and the second internal electrode layer contain a sub-component in addition to a main component, and
wherein the sub-component of the first internal electrode layer is different from the sub-component of the second internal electrode layer.

2. The multilayer ceramic electronic device as claimed in claim 1,
wherein the main component of the first internal electrode layer is same as the main component of the second internal electrode layer.

3. The multilayer ceramic electronic device as claimed in claim 1,
wherein the main component of the first internal electrode layer is different from the main component of the second internal electrode layer.

4. The multilayer ceramic electronic device as claimed in claim 1,
wherein a difference between a work function of the main component of the first internal electrode layer and a work function of the main component of the second internal electrode layer is 0.05 eV or less.

5. The multilayer ceramic electronic device as claimed in claim 1,
wherein the first internal electrode layer contains nickel as the main component and at least one element selected from iron, chromium, tin, vanadium, hafnium, osmium, ruthenium, silicon, boron, rhenium, copper, cobalt, tungsten, germanium, manganese, tantalum, silver, niobium, molybdenum, gallium, aluminum, zinc, indium, zirconium, magnesium, titanium, thallium, scandium, yttrium, or a lanthanoid element as the sub-component,
wherein the first internal electrode layer is connected to a first one of the external electrodes that is conductive to a terminal on a higher potential side when mounted on a substrate, and
wherein the second internal electrode layer is connected to a second one of the external electrodes that is conductive to a terminal on a lower potential side when mounted on the substrate.

6. The multilayer ceramic electronic device as claimed in claim 1,
wherein the first internal electrode layer contains copper as the main component and at least one element selected from iron, chromium, tin, vanadium, hafnium, tungsten, germanium, manganese, tantalum, silver, niobium, molybdenum, gallium, aluminum, zinc, indium, zirconium, magnesium, titanium, thallium, scandium, yttrium, or a lanthanoid element as the sub-component,
wherein the first internal electrode layer is connected to a first one of the external electrodes that is conductive to a terminal on a higher potential side when mounted on a substrate, and
wherein the second internal electrode layer is connected to a second one of the external electrodes that is conductive to a terminal on a lower potential side when mounted on a substrate.

7. The multilayer ceramic electronic device as claimed in claim 1,
wherein the second internal electrode layer contains nickel as the main component and at least one element selected from gold, platinum, iridium, palladium, or selenium as the sub-component,
wherein the first internal electrode layer is connected to a first one of the external electrodes that is conductive to a terminal on a higher potential side when mounted on a substrate, and
wherein the second internal electrode layer is connected to second one of the external electrodes that is conductive to a terminal on a lower potential side when mounted on a substrate.

8. The multilayer ceramic electronic device as claimed in claim 1,
wherein the second internal electrode layer contains copper as the main component and at least one element selected from gold, platinum, iridium, palladium, selenium, osmium, ruthenium, rhodium, silicon, or boron as the sub-component,
wherein the first internal electrode layer is connected to a first one of the external electrodes that is conductive to a terminal on a higher potential side when mounted on a substrate, and
wherein the second internal electrode layer is connected to a second one of the external electrodes that is conductive to a terminal on a lower potential side when mounted on the substrate.

9. The multilayer ceramic electronic device as claimed in claim 1,
wherein the main component of the first internal electrode layer and the main component of the second internal electrode layer are copper.

10. The multilayer ceramic electronic device as claimed in claim 1,
wherein the main component of the first internal electrode layer is nickel, and
wherein the main component of the second internal electrode layer is copper.

11. A circuit board comprising:
a multilayer ceramic electronic device as claimed in claim 1; and
a mounting board including a plurality of lands to which a first one of the external electrodes to which the first internal electrode layer is drawn out and a second one of the external electrodes to which the second internal electrode layer is drawn out are respectively connected.

12. A package comprising:
a multilayer ceramic electronic device as claimed in claim 1;
a carrier tape having a sealing face and a recess recessed from the sealing face for accommodating the multilayer ceramic electronic device; and
a top tape attached to the sealing face and covering the recess.
